(19) United States
(12) Patent Application Publication
(10) Pub. No.: US 2005/0062174 A1
(43) Pub. Date: Mar. 24, 2005

(54) Encapsulated organic electronic device

(75) Inventor: Andrew Ingle, Fremont, CA (US)

Correspondence Address: Siemens Corporation;Attn: Elsa Keller, Legal Administrator, Intellectual Property Department, 170 Wood Avenue South, Iselin, NJ, 08830, US

(73) Assignee: Osram Opto Semiconductors GmbH

(21) Appl. No.: 10/666,443

(22) Filed: Sep. 19, 2003

(51) Int. Cl. H01L 23/29

(52) U.S. Cl. 257/788

(57) ABSTRACT

In a first embodiment of the invention, an organic electronic device is encapsulated using an epoxy that includes a desiccant. The epoxy is around a perimeter of the organic electronic device. The epoxy bonds an encapsulation lid to a substrate and also absorbs oxygen and/or moisture. The desiccant in the epoxy is: barium oxide, calcium oxide, magnesium oxide, cobalt chloride, calcium chloride, calcium bromide, lithium chloride, zinc chloride, zinc bromide, sodium molevular, silicon dioxide, aluminum oxide, calcium sulfate, copper sulfate, potassium carbonate, magnesium carbonate, titanium dioxide, bentonite, acidic clay, montmorillonite, diatomaceous earth silica alumina, zeolite, silica, zirconia, activated carbon, or a mixture thereof.

### BACKGROUND OF THE INVENTION

Organic electronic devices such as, for example, an organic light emitting diode (“OLED”) display, an OLED light source used for general purpose lighting, an organic light sensor array, an organic transistor array, an organic solar cell array, and an organic laser array require protection from oxygen and moisture in the atmosphere. The oxygen or moisture adversely affect the inorganic materials such as, for example, the cathode and also adversely affect the organic materials of the device. The oxygen or moisture can cause dark spots due to cathode corrosion and/or delamination. In order to achieve the long lifetimes required for many applications, the organic electronic device is encapsulated (e.g., hermetically packaged).

FIG. 1 shows a cross-sectional view of a prior art encapsulated organic electronic device 106. In FIG. 1, an organic electronic device 112 is fabricated on a substrate 109. An epoxy 115 is applied around the perimeter of the organic electronic device 112. An encapsulation lid 121 has a desiccant cavity on an interior portion of the encapsulation lid 121 and a desiccant tablet 118 is placed in the desiccant cavity. The desiccant tablet 118 absorbs some portion of the oxygen and moisture that enter the encapsulated device 106. Oxygen and moisture may enter the device by permeating through the epoxy 115, or moisture may be generated within the device when the epoxy 115 is cured. The desiccant tablet 118 is typically comprised of fine metal particles that are held in place by a permeable membrane.

The encapsulation lid 121 is placed on the epoxy 115. The epoxy 115 bonds the encapsulation lid 121 to the substrate 109. The epoxy 115 is exposed to ultraviolet (“UV”) light or heat in order to cure it.

Some of the disadvantages of the encapsulated device 106 is the bulkiness of the resulting package due to the cap thickness needed to provide an adequately deep desiccant cavity. Also, some of the desiccant particles within the desiccant tablet 118 can leak through the permeable membrane and contaminate the organic electronic device (e.g., the desiccant particles can contaminate the cathode of the electronic device). Further, the additional manufacturing step of attaching the desiccant tablet 118 to the desiccant cavity within the encapsulation lid 121 increases the total accumulated cycle (“TAC”) time. Also, the pick-and-place equipment that places the desiccant tablet 118 into the desiccant cavity during manufacturing may misplace the desiccant such that it is not completely within the cavity; this misplacement can result in yield loss since some or all of the devices on the substrate may be defective due to improper sealing. In addition, the pick-and-place equipment due to its relatively high cost can be a large capital investment.

For the foregoing reasons, there exists a need to effectively encapsulate the organic electronic device while reducing the likelihood of device contamination, reducing the TAC time, reducing the yield loss, and also reducing the required capital investment.

### SUMMARY

A first embodiment of an encapsulated organic electronic device is described. The encapsulated device includes a substrate, an organic electronic device on the substrate, and an epoxy on the substrate that surrounds a perimeter of the organic electronic device. In addition, the encapsulated device also includes an encapsulation lid on the epoxy. The epoxy is a liquid or a gel when it is applied to the encapsulation lid or the substrate, and the epoxy includes a desiccant, and the desiccant can be: barium oxide, calcium oxide, magnesium oxide, cobalt chloride, calcium chloride, calcium bromide, lithium chloride, zinc chloride, zinc bromide, sodium molecular, silicon dioxide, aluminum oxide, calcium sulfate, copper sulfate, potassium carbonate, magnesium carbonate, titanium dioxide, bentonite, acidic clay, montmorillonite, diatomaceous earth silica alumina, zeolite, silica, zirconia, activated carbon, or a mixture thereof.

A second embodiment of an encapsulated organic electronic device is described. This encapsulated device includes a substrate, an organic electronic device on the substrate, and a desiccant ring on the substrate that surrounds a perimeter of the organic electronic device. In addition, the encapsulated device also includes an epoxy on the substrate that surrounds a perimeter of the desiccant ring. The encapsulated device also includes an encapsulation lid on the epoxy. Prior to applying the epoxy, the desiccant ring is evaporated onto the encapsulation lid and the desiccant ring is made of an alkali metal or an alkaline-earth metal.

### BRIEF DESCRIPTION OF THE DRAWINGS

FIG. 1 shows a prior art encapsulated organic electronic device.

FIG. 2 shows the prior art use of the adhesion layer extended to organic electronic device encapsulation.

FIG. 3 shows an embodiment of an encapsulated organic electronic device according to the present invention.

FIG. 4 shows an embodiment of multiple organic electronic devices that are encapsulated according to the present invention.

FIG. 5 shows an embodiment of a method to encapsulate an organic electronic device according to the present invention.

FIG. 6 shows a cross-sectional view of an embodiment of an OLED display.

### DETAILED DESCRIPTION

In a first embodiment of the invention, an organic electronic device is encapsulated using an epoxy that includes a desiccant. The epoxy is around a perimeter of the organic electronic device. The epoxy bonds an encapsulation lid to a substrate and also absorbs oxygen and/or moisture. The desiccant in the epoxy can be any one of: barium oxide, calcium oxide, magnesium oxide, cobalt chloride, calcium chloride, calcium bromide, lithium chloride, zinc chloride, zinc bromide, sodium molecular, silicon dioxide, aluminum oxide, calcium sulfate, copper sulfate, potassium carbonate, magnesium carbonate, titanium dioxide, bentonite, acidic clay, montmorillonite, diatomaceous earth silica alumina, zeolite, silica, zirconia, activated carbon, or a mixture thereof.

In a second embodiment of the invention, a desiccant ring is evaporated around a perimeter of the organic electronic device. The desiccant ring absorbs oxygen and/or moisture. In this embodiment, the desiccant ring is comprised of an alkali metal or an alkaline-earth metal. An epoxy is around a perimeter of the desiccant ring to bond the encapsulation lid to the substrate. The epoxy may or may not include desiccant material.

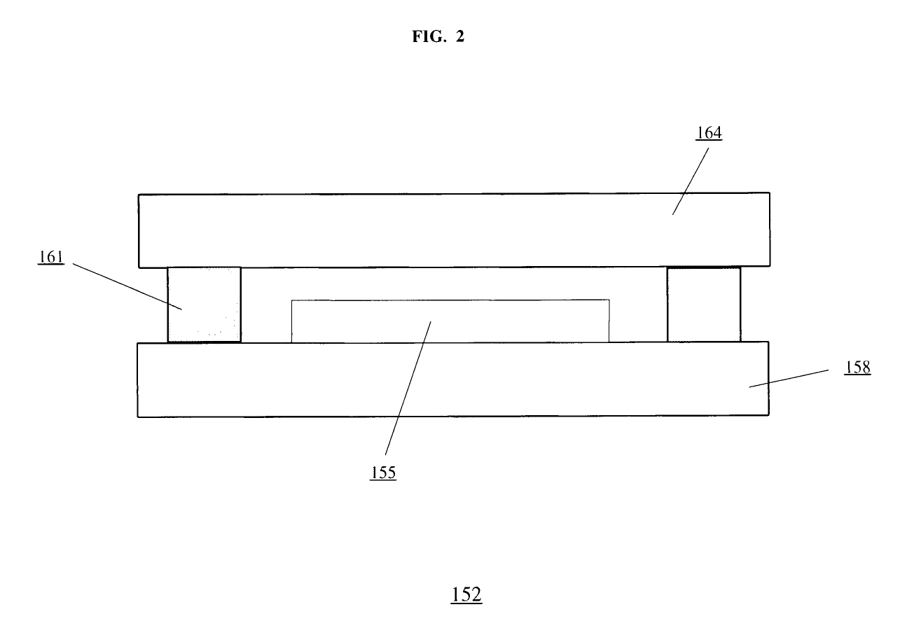

FIG. 2 shows a cross-sectional view of a first embodiment of an encapsulated organic electronic device 152 according to the present invention. In FIG. 2, an organic electronic device 155 is on a substrate 158. As used within the specification and the claims, the term “on” includes when objects (e.g., layers and devices) are in physical contact and when objects are separated by one or more intervening layers. The organic electronic device 155 can be, for example, a device that is sensitive to oxygen and/or moisture. Examples of such devices include an OLED display, an OLED light source used for general purpose lighting, an organic transistor array, an organic light sensor array, an organic solar cell array, or an organic laser array.

An epoxy 161 is on the substrate 158. The epoxy 161 is used to bond together the encapsulation lid 164 and the substrate 158. The epoxy 161 includes a desiccant and so the epoxy 161 also absorbs oxygen and/or moisture.

The encapsulation lid 164 is on the epoxy 161 and is over the organic electronic device 155. The encapsulation lid 164 is comprised of an opaque or a nonopaque material. The encapsulation lid 164 can be made of metal, glass, ceramics, or alternatively plastic with a barrier layer on the plastic. The epoxy 161 is cured by, for example, UV light or heat.

The epoxy 161 can be deposited on the encapsulation lid 164 or on the substrate 158. In this embodiment, when the epoxy 161 is deposited, it is a liquid or a gel (when the epoxy 161 is deposited, it is not in a solid state). The epoxy 161 is deposited such that when the substrate 158, the encapsulation lid 164, and the epoxy 161 are brought together, the epoxy 161 surrounds a perimeter of the organic electronic device 155.

The desiccant is ground into fine particles. The desiccant particles within the epoxy 161 have a high surface area. The larger the surface area, the more area that can come into contact with the reactive gasses resulting in the absorption of those gasses. An average particle size of the particles is less than 10 microns, preferably, less than 5 microns. A smaller particle size allows for more efficient loading and reduces the likelihood of the bond adhesion failing. The more efficient loading allows the epoxy seal 161 to be thinner thus making the device package thinner. Also, the thinner the epoxy 161, the less the epoxy surface area through which the reactive gasses can permeate.

The desiccant within the epoxy 161 can be any one of: barium oxide, calcium oxide, magnesium oxide, cobalt chloride, calcium chloride, calcium bromide, lithium chloride, zinc chloride, zinc bromide, sodium molevular, silicon dioxide, aluminum oxide, calcium sulfate, copper sulfate, potassium carbonate, magnesium carbonate, titanium dioxide, bentonite, acidic clay, montmorillonite, diatomaceous earth silica alumina, zeolite, silica, zirconia, activated carbon, or a mixture thereof.

The desiccant within the epoxy 161 absorbs oxygen and/or moisture and elinminates or minimizes the amount of reactive gasses permeating through the epoxy 161. By having the desiccant near the edges of the electronic device, the edges of the device's cathode strips can be better protected (e.g., the edges of the cathode are better protected if the rate of absorption of the desiccant is greater than the rate of absorption of the cathode edges). The reactive gasses can attack the edges of the cathode strips causing detrimental effects such as pixel shrinkage. The pixel shrinkage occurs when the reactive gasses that permeate through the epoxy 161 react with the edges of the cathode strips and the areas that react with the gasses no longer inject electrons resulting in no emission of light from these areas.

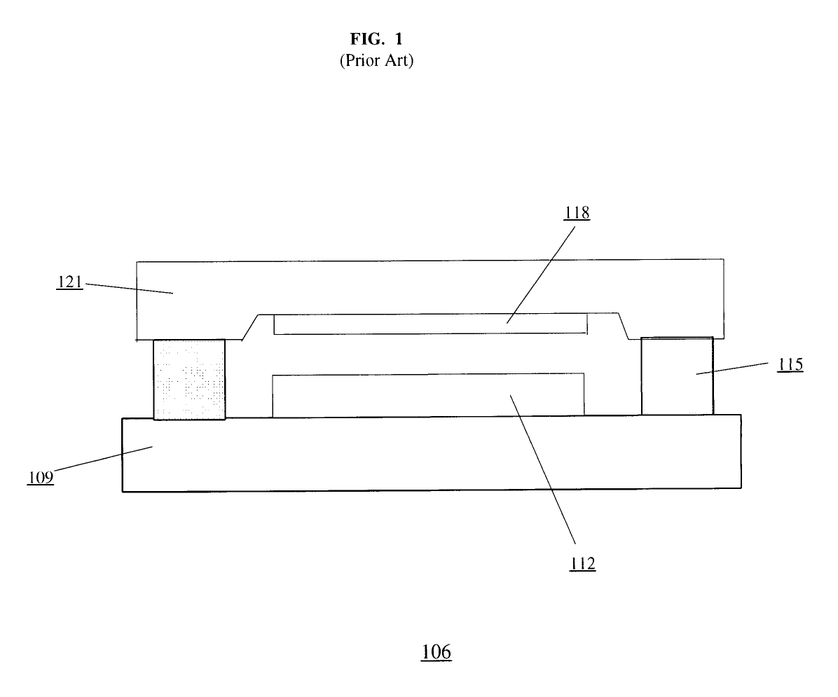

Since the epoxy 161 absorbs moisture and/or oxygen, the desiccant tablet 118 shown in FIG. 1 can be eliminated. By eliminating the desiccant tablet 118, the interior portion of the encapsulation lid 164 can be made flat (i.e., without the desiccant tablet 118, the desiccant cavity is no longer needed) and thus the encapsulated device (i.e., the device package) can be made thinner. For example, the thickness of the substrate 158 is typically 700 microns, and the thickness of an encapsulation lid with a desiccant cavity is typically 800 microns where the desiccant cavity typically has a depth of 200 microns. In this example, if the desiccant cavity is eliminated, then the encapsulation lid 164 can be made thinner by 100 to 200 microns thus resulting in a thinner encapsulated device. In addition, if the desiccant tablet 118 is eliminated, then the TAC time can be reduced since the time previously used to attach the desiccant tablet 118 to the encapsulation lid is eliminated. By using the epoxy 161 that includes the desiccants, only one step (i.e., the step of applying the epoxy) is used to encapsulate the organic electronic device. Further, by eliminating the desiccant tablet 118, the pick-and-place equipment is not used thus possibly improving device yield and reducing the cost to produce the encapsulated organic device. Also, if the desiccant tablet 118 is eliminated, then the likelihood of device contamination is reduced since the desiccant particles that may leak through the permeable membrane are eliminated. The desiccant particles in the epoxy 161 before or after curing cannot escape and thus contaminate the device.

Alternatively, in another configuration of the first embodiment of the device, the desiccant tablet 118 is attached to the encapsulation lid 164 and placed over the organic electronic device 155 in order to absorb the moisture and/or oxygen that enter the device package. By using both the desiccant tablet 18 attached to the encapsulation lid and the epoxy 161 that includes the desiccant, a greater amount of oxygen and/or moisture can be absorbed thus improving device lifetime. Alternatively or in addition to employing the desiccant tablet 118, a layer made of a reactive metal (e.g., ,alkaline-earth metals) or a reactive oxide (e.g., alkaline-earth metal oxides) can be deposited on the organic electronic device 155 in order to absorb the moisture and/or oxygen entering the device package.

In another configuration of the first embodiment of the device, rather than just one epoxy seal, multiple epoxy seals are applied to the encapsulation lid 164 or the substrate 158. In this configuration, each of the multiple epoxy seals includes the desiccant and therefore each of the seals absorbs moisture and/or oxygen. All of the multiple epoxy seals may be UV-curable, or all the epoxy seals may be thermal-curable, or some of the epoxy seals may be UV-curable while the others are thermal-curable.

Unlike a preformed transfer adhesive that is cured prior to being deposited on the encapsulation lid or the substrate, the epoxy 161 is in a liquid state when it is applied to the encapsulation lid or the substrate. The epoxy 161 is cured only after it is applied to the encapsulation lid or the substrate, and only after the encapsulation lid, the substrate, and the epoxy are brought together so that the epoxy contacts both the encapsulation lid and the substrate.

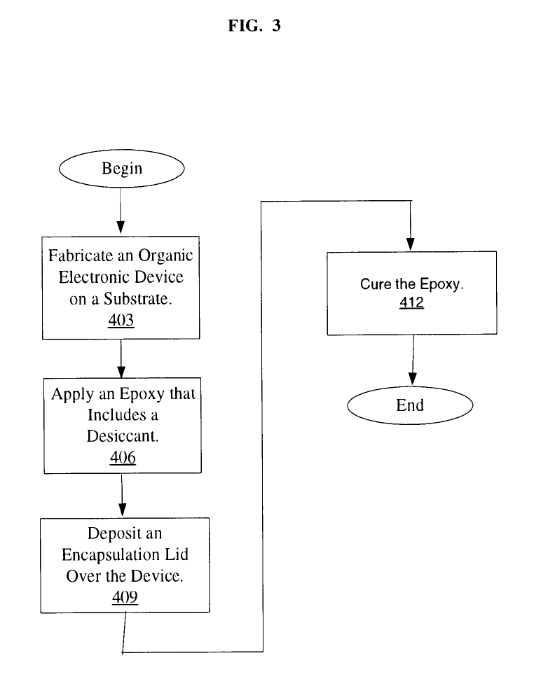

FIG. 3 shows a first embodiment of a method to encapsulate an organic electronic device according to the present invention. In block 403, an organic electronic device is fabricated on a substrate. In block 406, an epoxy that includes a desiccant is applied to the encapsulation lid or the substrate. The epoxy is used to bond an encapsulation lid to the substrate and also to absorb moisture and/or oxygen. The epoxy is applied such that when the encapsulation lid, the substrate, and the epoxy are brought together, the epoxy is around the perimeter of the organic electronic device. When the epoxy is applied to the encapsulation lid or the substrate, the epoxy is a liquid or a gel. The epoxy can be applied, for example, using a syringe needle or by screen printing. A shape of the epoxy is formed as the epoxy is applied to the encapsulation lid or the substrate.

Prior to application of the epoxy to the encapsulation lid or the substrate, the epoxy is formed by mixing different compounds. To form a thermal-cure epoxy, an epoxy resin and a desiccant can be mixed together to form an intermediate solution. Then, a hardener and the intermediate solution are mixed together to form the thermal-cure epoxy. The hardener reacts with the epoxy resin to harden the resin. In addition, fillers can be mixed in with the desiccant and the epoxy resin or with the hardener to give the resulting epoxy specific properties such as, for example, flexibility, durability, rheology, and impact resistance. Examples of the epoxy resin are “DEN-431” available from Dow Chemical Company, and “EPON 881” available from Shell Chemical Company. Examples of the fillers are fumed silica (affects thixotropic properties), talc (affects permeability), and antimony trioxide (affects flame retardancy). An example of the hardener is Amicure 2049 from Air Products. Examples of the desiccant were listed above.

To form a UV-curable epoxy, an epoxy resin, a desiccant, a hardener, and a UV-catalyst are mixed together to form the epoxy. In addition, fillers can be mixed in with these compounds to give the resulting epoxy specific properties. Examples of UV catalysts are: organic metal complex salts comprising ligands such as cyclopentadienyl anion, indenyl anion, (xylene)hexafluoroantimonate anion or hexafluorophosphate anion and metal cations such as iron, chromium, molybdenum, tungsten, manganese, rhenium, ruthenium or osmium.

In block 409, an encapsulation lid is deposited over the organic electronic device such that the epoxy is in contact with both the encapsulation lid and the substrate. The epoxy bonds the encapsulation lid to the substrate in order to encapsulate the device. In block 412, the epoxy is cured (i.e., the epoxy resins cross-link and this strengthens the bond between the encapsulation lid and the substrate). If the epoxy is a thermal-cure epoxy, then this epoxy is cured by applying heat. If the epoxy is a UV-curable epoxy, then this epoxy is cured by applying UV radiation.

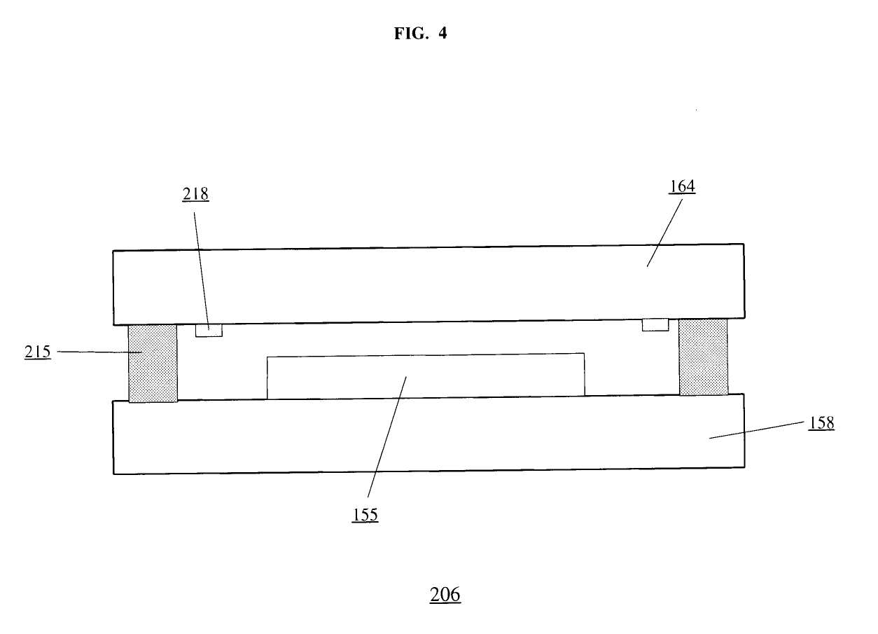

FIG. 4 shows a cross-sectional view of a second embodiment of the encapsulated organic electronic device 206 according to the present invention. In FIG. 4, an organic electronic device 155 is on a substrate 158. An epoxy 215 is on the substrate 158. The encapsulation lid 164 is on the epoxy 215. The epoxy 215 is used to bond the encapsulation lid 164 to the substrate 158.

A desiccant ring 218 is on the encapsulation lid 164. The desiccant ring 218 is evaporated onto the encapsulation ring 164. The desiccant ring 218 is made of a reactive metal (e.g., ,alkaline-earth metals (i.e., metals in Group 1A of the Periodic Table)) or a reactive oxide (e.g., alkaline-earth metal oxides (i.e., metals in Group IIA of the Periodic Table)). For example, the desiccant ring 218 can be made of barium or calcium. The desiccant ring 218 absorbs the moisture and/or oxygen that have entered the device package. The desiccant ring 218 is not used to bond the encapsulation lid 164 to the substrate 158. Preferably, the desiccant ring 218 has a height that ranges from 300 nm up to 1 micron. Since most of the reactive gasses enter the device package by permeating through the epoxy 215, the desiccant ring 218 is placed near the epoxy 215 to absorb the moisture and/or oxygen entering the device package. Also, the desiccant ring 218 is near the edges of the electronic device to better protect the edges of the device's cathode strips. The reactive gasses can attack the edges of the cathode strips causing detrimental effects such as pixel shrinkage.

The epoxy 215 can be formulated such that it absorbs moisture and/or oxygen, or alternatively, the epoxy 215 can be formulated without using any desiccants so that it does not absorb moisture and/or oxygen. If, the epoxy 215 does absorb moisture and/or oxygen, then the epoxy 215 includes any of the desiccants listed above. The epoxy 215 is cured only after it is applied to the encapsulation lid 164 or the substrate 158.

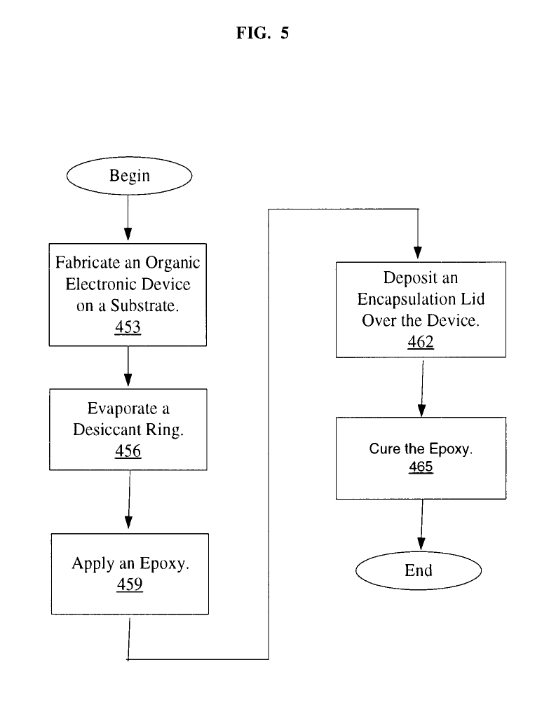

FIG. 5 shows a second embodiment of the method to encapsulate an organic electronic device according to the present invention. In block 453, an organic electronic device is fabricated on a substrate. In block 456, the desiccant ring is evaporated onto the encapsulation lid. Shadow masks, for example, can be used to precisely deposit the desiccant on the encapsulation lid. The desiccant ring is evaporated such that when the substrate, the encapsulation lid, and the epoxy are brought together, the desiccant ring is around a perimeter of the device. The desiccant ring absorbs moisture and/or oxygen, however, it is not used to bond the encapsulation lid to the substrate. The desiccant ring is near the epoxy and also near the edges of the electronic device to absorb the moisture and/or oxygen permeating through the epoxy and also to protect the edges of the electronic device.

In block 459, an epoxy is applied to the encapsulation lid or the substrate. The epoxy is used to bond the encapsulation lid to the substrate. The epoxy is applied such that when the encapsulation lid, the substrate, and the epoxy are brought together, the epoxy is around the perimeter of the organic electronic device. When the epoxy is applied to the encapsulation lid or the substrate, the epoxy is a liquid or a gel. The epoxy can be formulated such that it absorbs moisture and/or oxygen, or alternatively, the epoxy can be formulated without using any desiccants so that it does not absorb moisture and/or oxygen.

In block 462, an encapsulation lid is deposited over the organic electronic device such that the epoxy is in contact with both the encapsulation lid and the substrate. The epoxy bonds the encapsulation lid to the substrate in order to encapsulate the device. In block 465, the epoxy is cured. If the epoxy is a thermal-cure epoxy, then this epoxy is cured by applying heat. If the epoxy is a UV-curable epoxy, then this epoxy is cured by applying UV radiation.

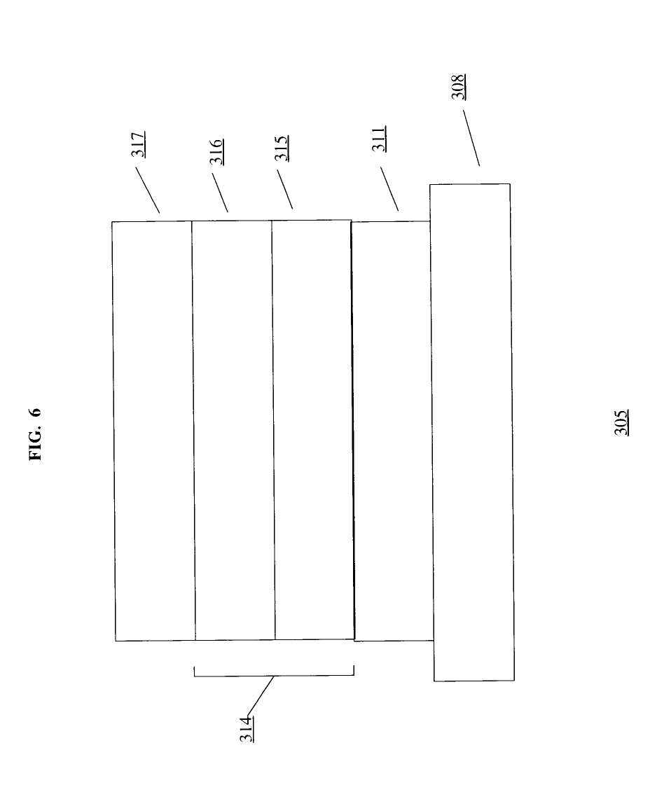

The organic electronic device can be an OLED display. FIG. 6 shows a cross-sectional view of an embodiment of an OLED display 305. The OLED display 305 includes a substrate 308 and a first electrode 311 on the substrate 308. The first electrode 311 may be patterned for pixilated applications or unpatterned for backlight applications. The OLED display305 also includes a semiconductor stack 314 on the first electrode 311. The semiconductor stack 314 includes at least the following: (1) a hole transporting layer (“HTL”) 315 and (2) an emissive layer 316. If the first electrode 311 is an anode, then the HTL 315 is on the first electrode 311, and the emissive layer 316 is on the HTL 315 (this configuration is shown in FIG. 6). Alternatively, if the first electrode 311 is a cathode (not shown), then the emissive layer 316 is on the first electrode 311, and the HTL 315 is on the emissive layer 316. The OLED display305 also includes a second electrode 317 on the semiconductor stack 314. Other layers than that shown in FIG. 6 may also be added including insulating layers between the first electrode 311 and the semiconductor stack 314, and/or between the semiconductor stack 314 and the second electrode 317. These layers are described in greater detail below.

Substrate 308:

The substrate 308 can be any material, which can support the layers, and is transparent or semi-transparent to the wavelength of light generated in the device. The substrate 308 can be transparent or opaque (e.g., the opaque substrate is used in top-emitting devices). By modifying or filtering the wavelength of light which can pass through the substrate, the color of light emitted by the device can be changed. Preferable substrate materials include glass, quartz, silicon, and plastic, preferably, thin, flexible glass. The preferred thickness of the substrate 308 depends on the material used and on the application of the device. The substrate 308 can be in the form of a sheet or continuous film. The continuous film is used, for example, for roll-to-roll manufacturing processes which are particularly suited for plastic, metal, and metallized plastic foils.

First Electrode 311:

In one configuration of this embodiment, the first electrode 311 functions as an anode (the anode is a conductive layer which serves as a hole-injecting layer and which comprises a material with work function greater than about 4.5 eV). Typical anode materials include metals (such as platinum, gold, palladium, indium, and the like); metal oxides (such as lead oxide, tin oxide, ITO, and the like); graphite; doped inorganic semiconductors (such as silicon, germanium, gallium arsenide, and the like); and doped conducting polymers (such as polyaniline, polypyrrole, polythiophene, and the like).

In an alternative configuration, the first electrode layer 311 functions as a cathode (the cathode is a conductive layer which serves as an electron-injecting layer and which comprises a material with a low work function). The cathode, rather than the anode, is deposited on the substrate 308 in the case of, for example, a top-emitting OLED. Typical cathode materials are listed below in the section for the “second electrode 317”.

The first electrode 311 can be transparent, semi-transparent, or opaque to the wavelength of light generated within the device. Preferably, the thickness of the first electrode 311 is from about 10 nm to about 1000 nm, more preferably from about 50 nm to about 200 nm, and most preferably is about 100.

The first electrode layer 311 can typically be fabricated using any of the techniques known in the art for deposition of thin films, including, for example, vacuum evaporation, sputtering, electron beam deposition, or chemical vapor deposition, using for example, pure metals or alloys, or other film precursors.

HTL 315:

The HTL 315 has a higher hole mobility than electron mobility and is used to effectively transport holes from the anode 211. The HTL can be comprised of polymers or small molecule materials. The HTL 315 can be comprised of, for example, PEDOT:PSS”, or polyaniline (“PANI”).

The HTL 315 functions as: (1) a buffer to provide a good bond to the substrate; and/or (2) a hole injection layer to promote hole injection; and/or (3) a hole transport layer to promote hole transport.

Preferably, the thickness of the HTL 315 is from about 5 to about 1000 nm, more preferably from about 20 to about 500 nm, and most preferably from about 50 to about 250 nm.

The HTL 315 can be deposited using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating.

Emissive Layer 316:

The emissive layer 316 is comprised of an electroluminescent material that due to recombinations between electrons and holes can emit light. A preferred organic electroluminescent material that emits yellow light and includes polyphenelenevinylene derivatives is available as PDY132 from Covion Organic Semiconductors GmbH, Industrial park Hoechst, Frankfurt, Germany. Another preferred organic electroluminescent material that emits green light and includes fluorene-copolymers is available as Lumation Green 1300 series from Dow Chemical, Midland, Mich.

Alternatively, rather than polymers, small organic molecules that emit by fluorescence or by phosphorescence can serve as the organic electroluminescent layer. Examples of small-molecule organic electroluminescent materials include: (i) tris(8-hydroxyquinolinato) aluminum (Alq); (ii) 1,3-bis(N,N-dimethylaminophenyl)-1,3,4-oxidazole (OXD-8); (iii)-oxo-bis(2-methyl-8-quinolinato)aluminum; (iv) bis(2-methyl-8-hydroxyquinolinato) aluminum; (v) bis(hydroxybenzoquinolinato) beryllium (BeQ.sub.2); (vi) bis(diphenylvinyl)biphenylene (DPVBI); and (vii) arylamine-substituted distyrylarylene (DSA amine).

The thickness of emissive layer 316 is from about 5 nm to about 500 nm, preferably, from about 20 nm to about 100 nm, and more preferably is about 75 nm.

The emissive layer 316 can be deposited using selective deposition techniques or nonselective deposition techniques.

Second Electrode 317:

In one configuration of this embodiment, the second electrode layer 317 functions as a cathode (the cathode is a conductive layer which serves as an electron-injecting layer and which comprises a material with a low work function). While the cathode can be comprised of many different materials, preferable materials include aluminum, silver, magnesium, calcium, barium, or combinations thereof. More preferably, the cathode is comprised of aluminum, aluminum alloys, or combinations of magnesium and silver.

In an alternative configuration, the second electrode layer 317 functions as an anode (the anode is a conductive layer which serves as a hole-injecting layer and which comprises a material with work function greater than about 4.5 eV). The anode, rather than the cathode, is deposited on the semiconductor stack 314 in the case of, for example, a top-emitting OLED. Typical anode materials are listed earlier in the section for the “first electrode 311”.

The OLED display is desirable for use in electronic media because of their thin profile, low weight, capability of obtaining a wide variety of emission colors, high contrast, and low driving voltage, i.e., less than about 20 volts. The OLED display described above can be used in applications such as, for example, computer displays, information displays in vehicles, television monitors, telephones, printers, and illuminated signs.

As any person of ordinary skill in the art of organic electronic device fabrication will recognize from the description, figures, and examples that modifications and changes can be made to the embodiments of the invention without departing from the scope of the invention defined by the following claims.

1. An encapsulated organic electronic device, comprising:
a substrate;
an organic electronic device on said substrate;
an epoxy on said substrate, said epoxy surrounds a perimeter of said organic electronic device; and
an encapsulation lid on said epoxy,
wherein said epoxy is a liquid or a gel when it is applied to said encapsulation lid or said substrate, and said epoxy includes a desiccant, said desiccant is: barium oxide, calcium oxide, magnesium oxide, cobalt chloride, calcium chloride, calcium bromide, lithium chloride, zinc chloride, zinc bromide, sodium molevular, silicon dioxide, aluminum oxide, calcium sulfate, copper sulfate, potassium carbonate, magnesium carbonate, titanium dioxide, bentonite, acidic clay, montmorillonite, diatomaceous earth silica alumina, zeolite, silica, zirconia, activated carbon, or a mixture thereof.

2. The encapsulated organic electronic device of claim 1 wherein said epoxy bonds said encapsulation lid to said substrate, and absorbs at least one of: oxygen and moisture.

3. The encapsulated organic electronic device of claim 1 wherein an interior portion of said encapsulation lid does not have a cavity.

4. The encapsulated organic electronic device of claim 1 wherein said epoxy is applied using a syringe needle or by screen printing.

5. The encapsulated organic electronic device of claim 1 wherein said epoxy further includes an epoxy resin, and a hardener.

6. The encapsulated organic electronic device of claim 5 wherein said epoxy further includes at least one filler.

7. The encapsulated organic electronic device of claim 1 wherein said desiccant is a finely particulated solid and an average particle size is less than 10 microns.

8. The encapsulated organic electronic device of claim 1 wherein said epoxy is cured only after said epoxy is applied on said encapsulation lid or said substrate.

9. The encapsulated organic electronic device of claim 1 wherein said organic electronic device is an OLED display, an OLED light source used for general purpose lighting, an organic transistor array, an organic light sensor array, an organic solar cell array, or an organic laser array.

10. A method to encapsulate an organic electronic device, comprising:
fabricating said organic electronic device on a substrate;
applying an epoxy on an encapsulation lid or on said substrate such that when said encapsulation lid, said substrate, and said epoxy are brought together, said epoxy is around a perimeter of said organic electronic device;
depositing an encapsulation lid over said organic electronic device such that said epoxy contacts both said substrate and said encapsulation lid to encapsulate said organic electronic device; and
curing said epoxy,
wherein said epoxy is a liquid or a gel when it is applied to said encapsulation lid or said substrate, and said epoxy includes a desiccant, said desiccant is: barium oxide, calcium oxide, magnesium oxide, cobalt chloride, calcium chloride, calcium bromide, lithium chloride, zinc chloride, zinc bromide, sodium molevular, silicon dioxide, aluminum oxide, calcium sulfate, copper sulfate, potassium carbonate, magnesium carbonate, titanium dioxide, bentonite, acidic clay, montmorillonite, diatomaceous earth silica alumina, zeolite, silica, zirconia, activated carbon, or a mixture thereof.

11. The method of claim 10 wherein said epoxy bonds said encapsulation lid to said substrate, and absorbs at least one of: oxygen and moisture.

12. The method of claim 10 wherein an interior portion of said encapsulation lid does not have a cavity.

13. The method of claim 10 further comprising shaping said epoxy as said epoxy is applied on said encapsulation lid or on said substrate such that when said encapsulation lid, said substrate, and said epoxy are brought together, said epoxy is around a perimeter of said organic electronic device.

14. The method of claim 10 wherein said epoxy is applied using a syringe needle or by screen printing.

15. The method of claim 10 further comprising, prior to applying said epoxy, forming said epoxy by mixing said desiccant with an epoxy resin to form a solution and then mixing said solution with a hardener to form said epoxy.

16. The method of claim 10 further comprising, prior to applying said epoxy, forming said epoxy by mixing said desiccant, an epoxy resin, a hardener, and a UV-catalyst to form said epoxy.

17. The method of claim 10 further comprising, prior to applying said epoxy, grinding said desiccant into a plurality of particles with a high surface area, wherein an average particle size of said plurality of particles is less than 10 microns.

18. The method of claim 10 wherein said epoxy is cured only after it is applied on said encapsulation lid or said substrate.

19. The method of claim 10 wherein a shape of said epoxy is formed as said epoxy is applied to said encapsulation lid or said substrate.

20. The method of claim 10 wherein said organic electronic device is an OLED display, an OLED light source used for general purpose lighting, an organic transistor array, an organic light sensor array, an organic solar cell array, or an organic laser array.

21. An encapsulated organic electronic device, comprising:
a substrate:
an organic electronic device on said substrate;
a desiccant ring on said substrate, said desiccant ring surrounds a perimeter of said organic electronic device;
an epoxy on said substrate, said epoxy surrounds a perimeter of said desiccant ring; and
an encapsulation lid on said epoxy,
wherein prior to applying said epoxy, said desiccant ring is evaporated onto said encapsulation lid, said desiccant ring is made of: an alkali metal or an alkaline-earth metal.

22. The encapsulated organic electronic device of claim 21 wherein said desiccant ring is comprised of barium or calcium.

23. The encapsulated organic electronic device of claim 21 wherein said desiccant ring absorbs at least one of: oxygen and moisture.

24. The encapsulated organic electronic device of claim 21 wherein a height of said desiccant ring has a range between 300 nm to 1 micron.

25. The encapsulated organic electronic device of claim 21 wherein said epoxy does not absorb oxygen or moisture.

26. The encapsulated organic electronic device of claim 21 wherein said epoxy absorbs at least one of: oxygen and moisture.

27. The encapsulated organic electronic device of claim 26 wherein said epoxy includes a desiccant, said desiccant is: barium oxide, calcium oxide, magnesium oxide, cobalt chloride, calcium chloride, calcium bronide, lithium chloride, zinc chloride, zinc bromide, sodium molevular, silicon dioxide, aluminum oxide, calcium sulfate, copper sulfate, potassium carbonate, magnesium carbonate, titanium dioxide, bentonite, acidic clay, montmorillonite, diatomaceous earth silica alumina, zeolite, silica, zirconia, activated carbon, or a mixture thereof.

28. The encapsulated organic electronic device of claim 21 wherein an interior portion of said encapsulation lid does not have a cavity.

29. The encapsulated organic electronic device of claim 21 wherein said organic electronic device is an OLED display, an OLED light source used for general purpose lighting, an organic transistor array, an organic light sensor array, an organic solar cell array, or an organic laser array.

30. A method to encapsulate an organic electronic device, comprising:
fabricating said organic electronic device on a substrate;
evaporating an desiccant ring on an encapsulation lid such that when said substrate, said encapsulation lid, and an epoxy are brought together, said desiccant ring is around a perimeter of said organic electronic device;
applying an epoxy on said encapsulation lid or on said substrate such that when said substrate, said encapsulation lid, and said epoxy are brought together, said epoxy is around a perimeter of said desiccant ring; and
depositing an encapsulation lid over said organic electronic device such that said epoxy contacts both said substrate and said encapsulation lid to encapsulate said organic electronic device,
wherein said desiccant ring is made of: an alkali metal or an alkaline-earth metal.

31. The method of claim 30 wherein said desiccant ring is comprised of barium or calcium.

32. The method of claim 30 wherein said desiccant ring absorbs at least one of:
oxygen and moisture.

33. The method of claim 30 wherein a height of said desiccant ring has a range between 300 nm to 1 micron.

34. The method of claim 30 wherein said epoxy includes a desiccant, said desiccant is: barium oxide, calcium oxide, magnesium oxide, cobalt chloride, calcium chloride, calcium bromide, lithium chloride, zinc chloride, zinc bromide, sodium molevular, silicon dioxide, aluminum oxide, calcium sulfate, copper sulfate, potassium carbonate, magnesium carbonate, titanium dioxide, bentonite, acidic clay, montmorillonite, diatomaceous earth silica alumina, zeolite, silica, zirconia, activated carbon, or a mixture thereof.
